(19) United States
(12) Patent Application Publication
(10) Pub. No.: US 2026/0096051 A1
(43) Pub. Date: Apr. 2, 2026

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Kazuhiko Tsuchiya, Kakegawa-shi (JP)

(21) Appl. No.: 19/342,745

(22) Filed: Sep. 29, 2025

(30) Foreign Application Priority Data
Oct. 1, 2024 (JP) 2024-172098

(51) Int. Cl. H05K 7/20; H05K 1/02; H05K 1/181; H05K 7/02

(52) U.S. Cl. CPC H05K 7/20127; H05K 1/0203; H05K 1/181; H05K 7/026; H05K 2201/10189; H05K 2201/10272; H05K 2201/10522

(57) ABSTRACT

An electrical connection unit includes a unit body, a first cover that covers the unit body from a first side in a first direction, a second cover that covers the unit body from a second side in the first direction, and a routing member that is provided integrally with the first cover and is detachably connected to the unit body. The unit body includes an insulating base member, a bus bar, a plurality of electronic components each having a terminal connected to the bus bar and a connector connection portion, and a plurality of connector members each having a first connector detachably connected to the connector connection portion and a second connector disposed in a first direction. The routing member includes a plurality of relay connectors insertable into and removable from the second connectors of the plurality of connector members, and a support integrally supporting the plurality of relay connectors.

### TECHNICAL FIELD

Embodiments of the present invention relate to an electrical connection unit.

Priority is claimed on Japanese Patent Application No. 2024-172098 filed in Japan on Oct. 1, 2024, the content of which is incorporated herein by reference.

### BACKGROUND ART

An electrical connection unit having a housing that accommodates electronic components and a bus bar attached to the housing in a standing posture is known.

### PRIOR ART DOCUMENT

### Patent Document

[Patent Document 1] Japanese Unexamined Patent Application, First Publication No. 2024-037492

### SUMMARY OF THE INVENTION

### Problems to be Solved by the Invention

It is desirable to improve assemblability of an assembly including an electrical connection unit.

An embodiment provides an assembly capable of improving assemblability.

### Means for Solving the Problem

An electrical connection unit according to one embodiment includes a unit body, a first cover that covers the unit body from a first side in a first direction, a second cover that covers the unit body from a second side in the first direction, and a routing member that is provided integrally with the first cover and is detachably connected to the unit body. The unit body includes an insulating base member including a plate-shaped or sheet-shaped flat surface portion, a conductive bus bar held by the flat surface portion, a plurality of electronic components provided on a first side in the first direction with respect to the base member and each including a terminal electrically connected to the bus bar and a connector connection portion, and a plurality of connector members each including a first connector detachably connected to the connector connection portion and a second connector disposed in the first direction. The routing member includes a plurality of relay connectors provided at positions corresponding to the second connectors of the plurality of connector members when viewed from the first direction and insertable into and removable from the second connectors of the plurality of connector members in the first direction, and a support integrally supporting the plurality of relay connectors.

### Effects of Invention

According to one embodiment, the assemblability of the electrical connection unit can be improved.

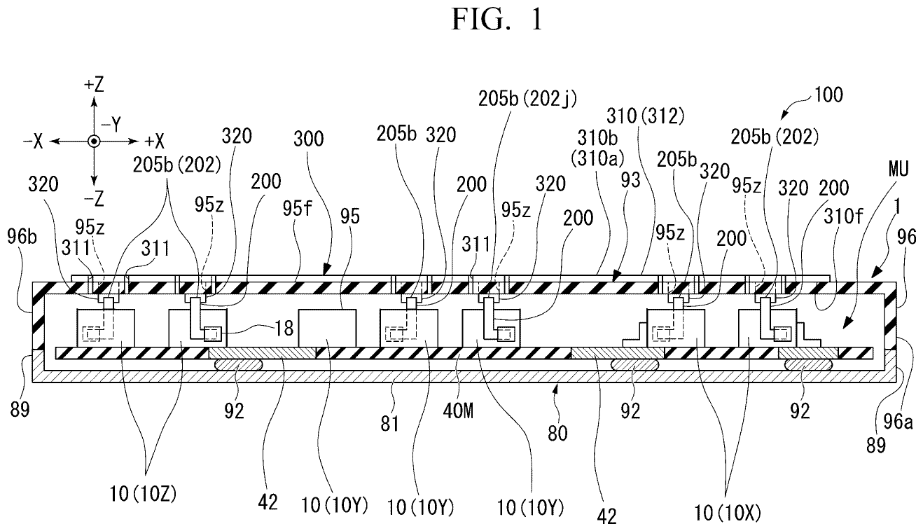

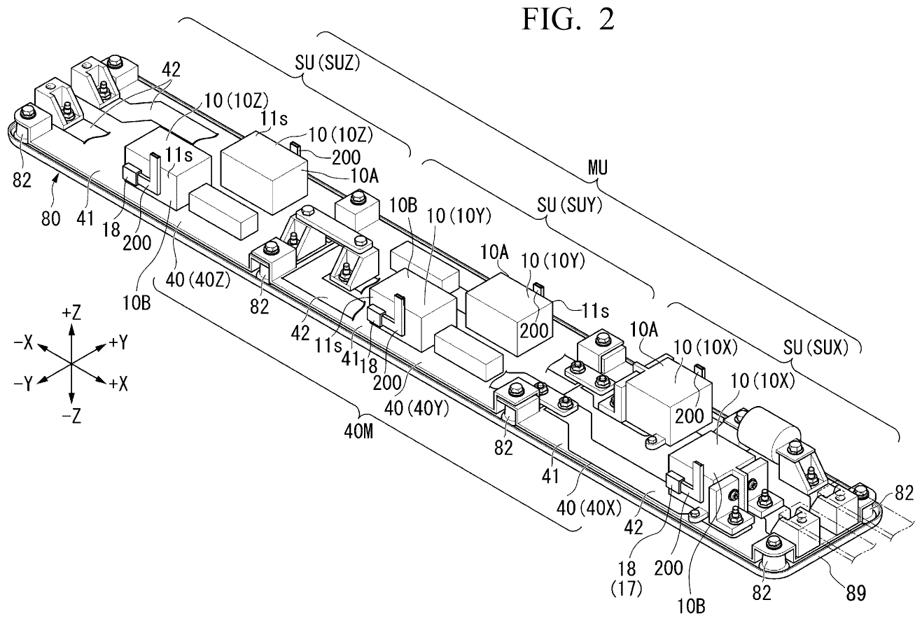

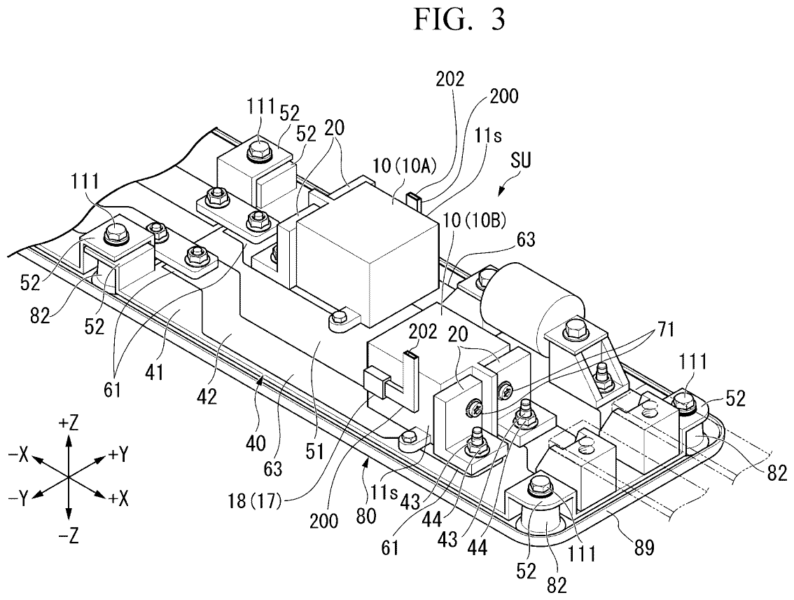

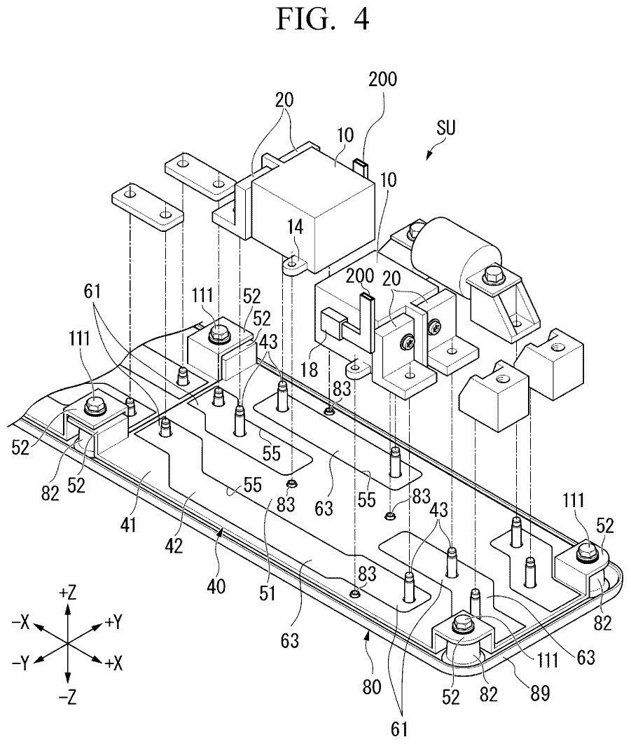

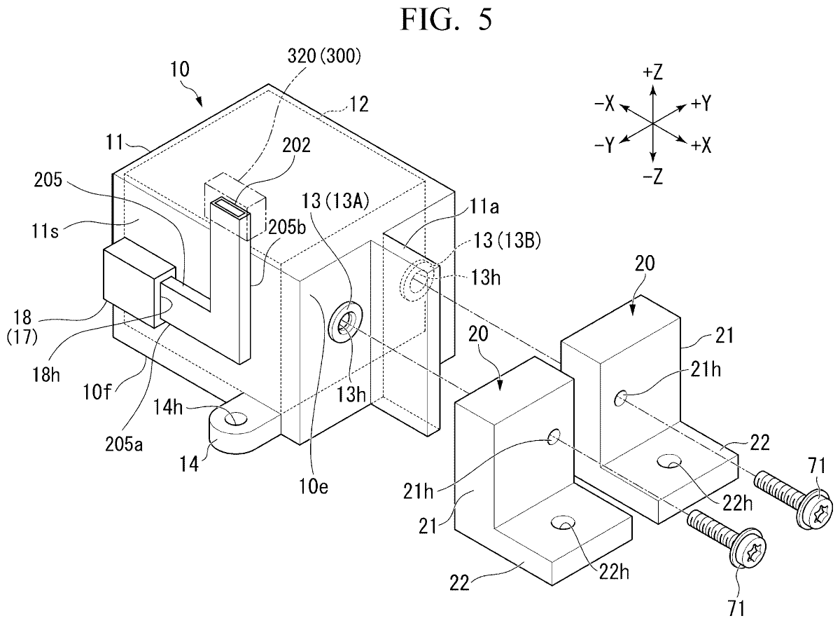

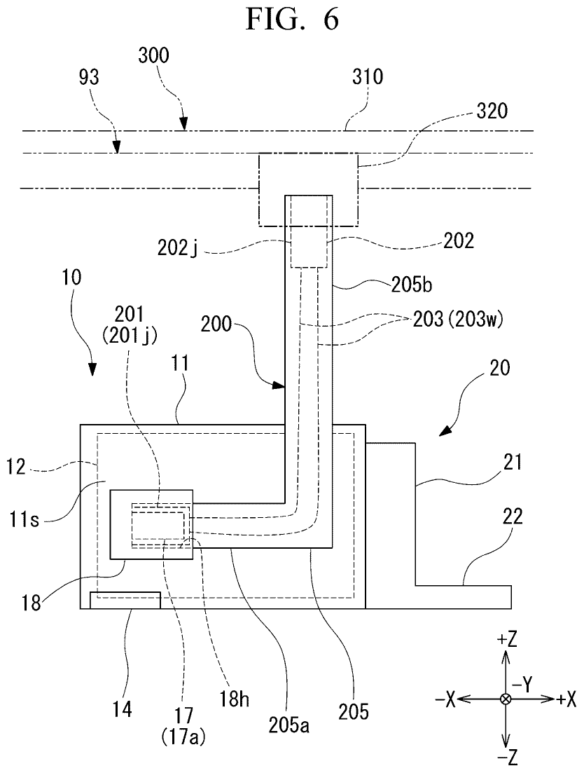

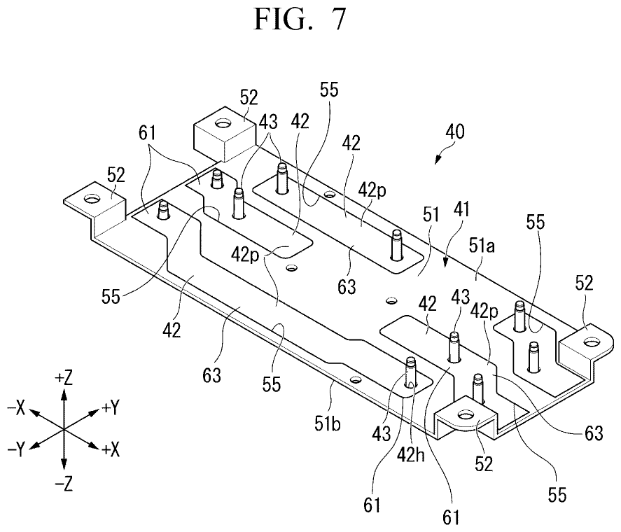

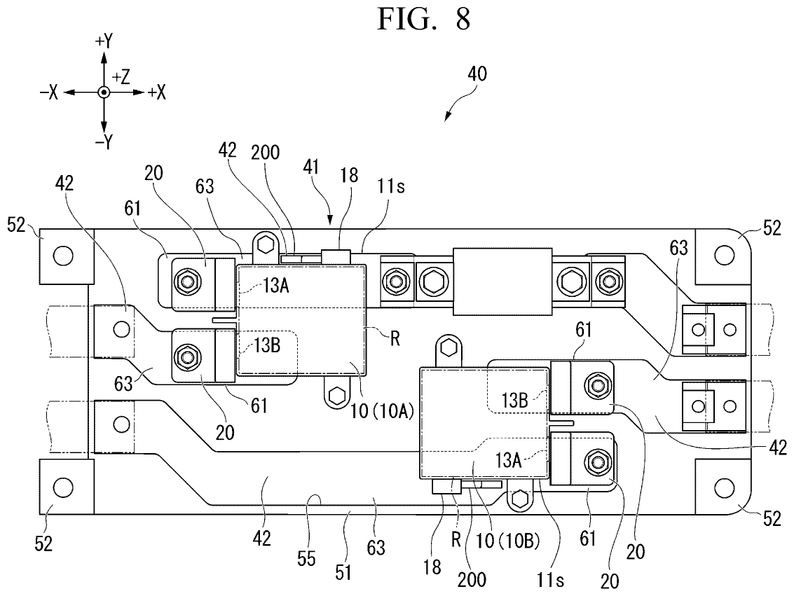

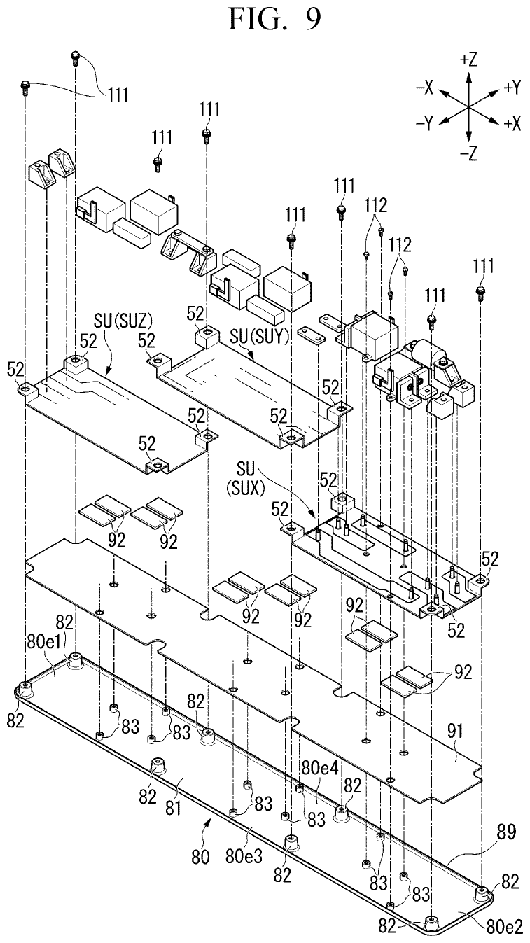

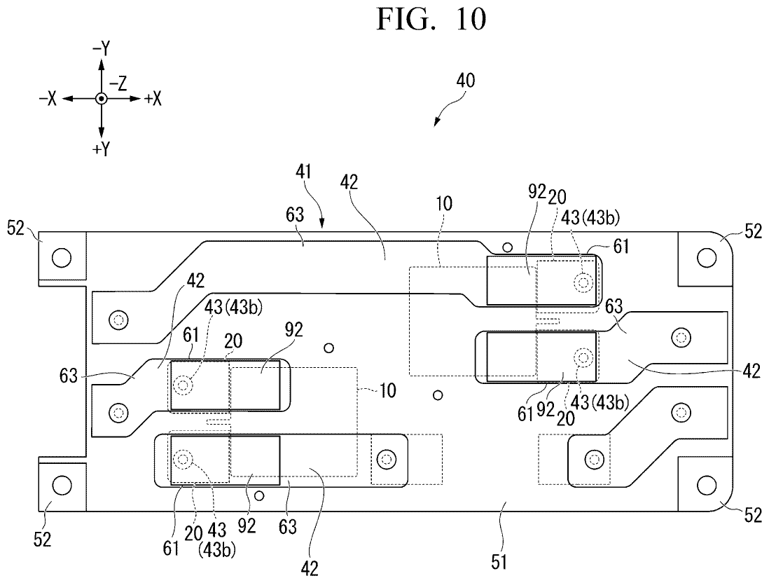

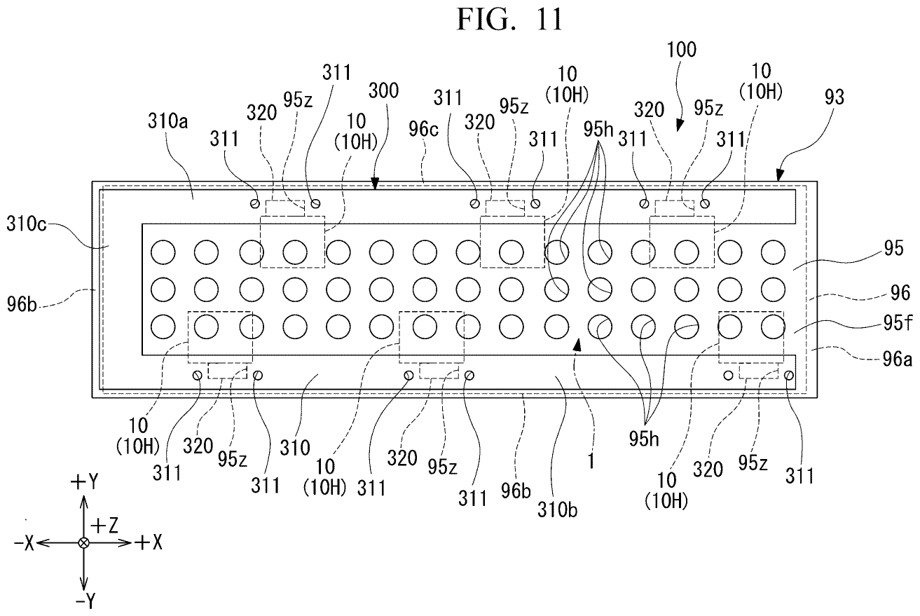

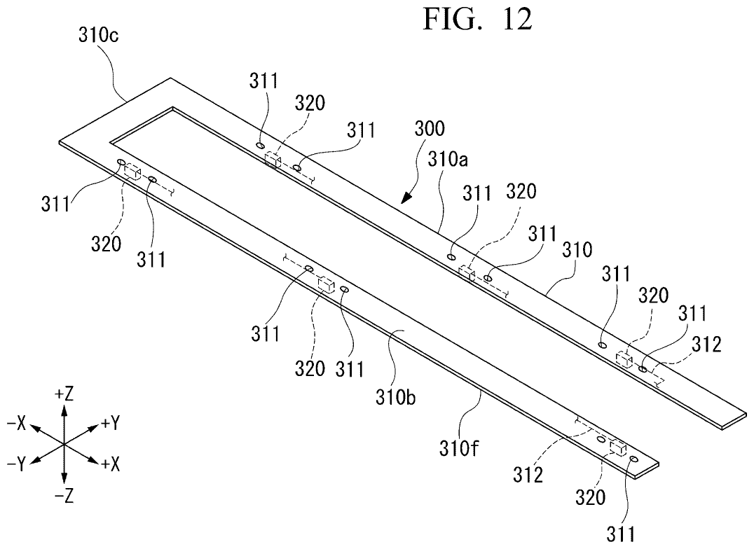

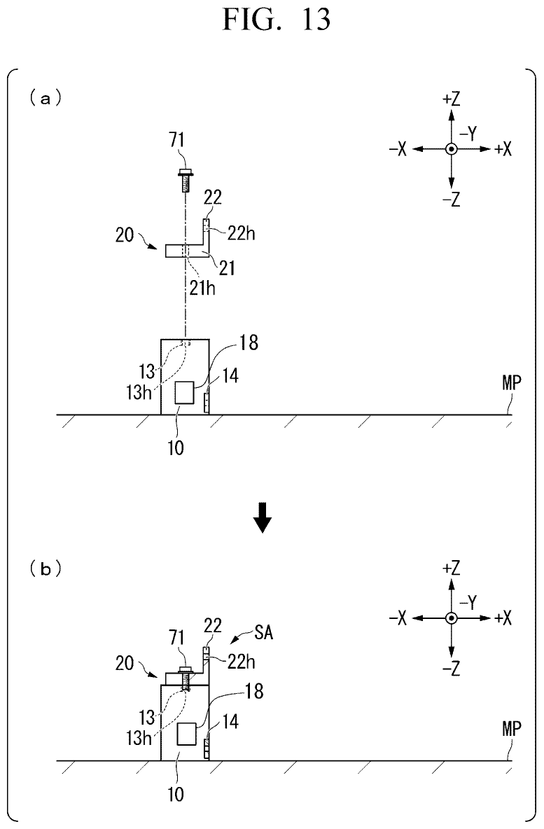

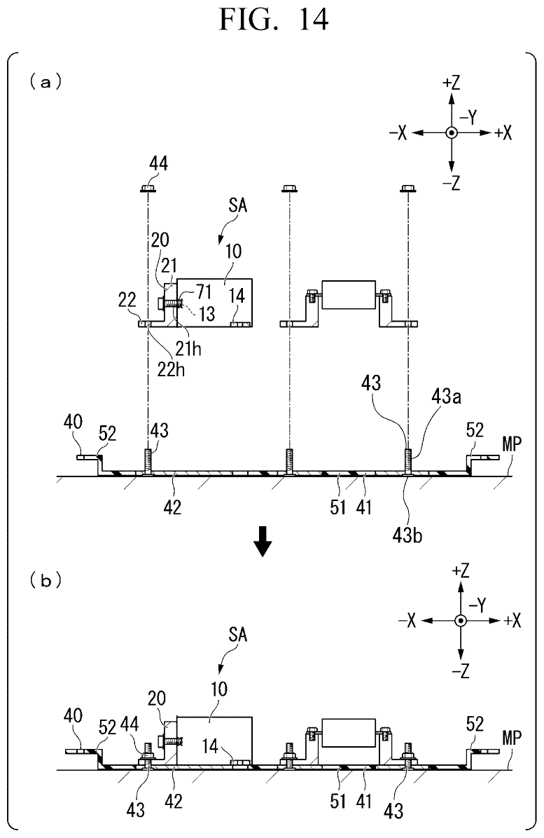

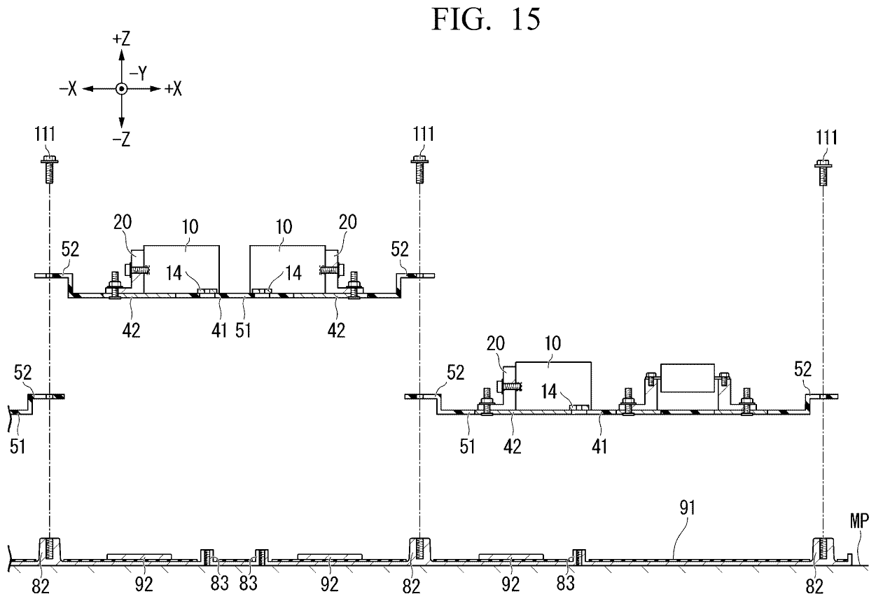

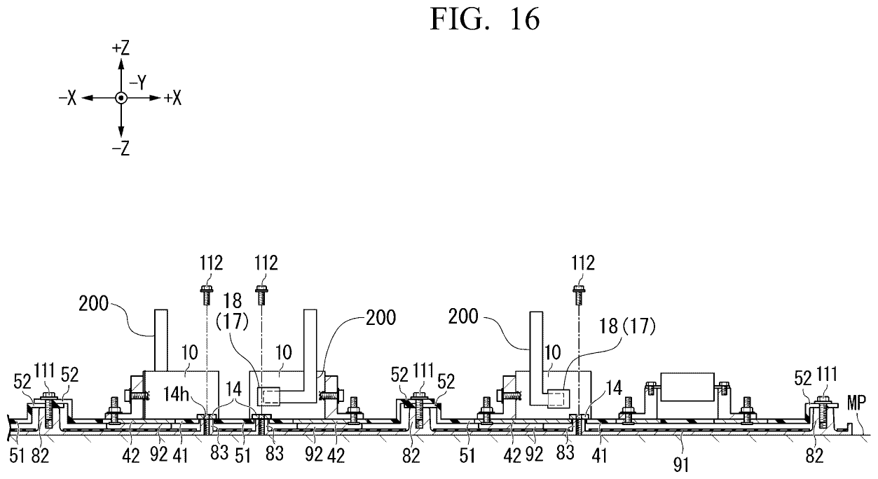

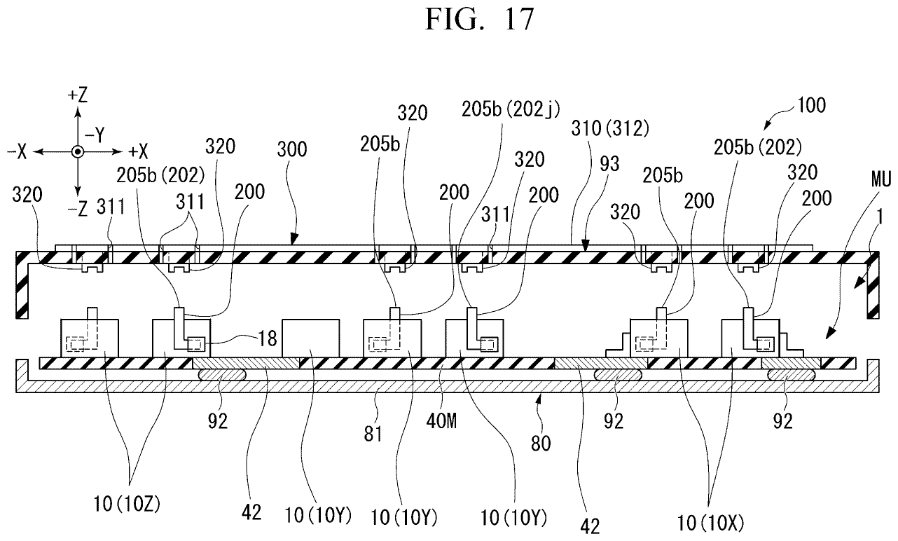

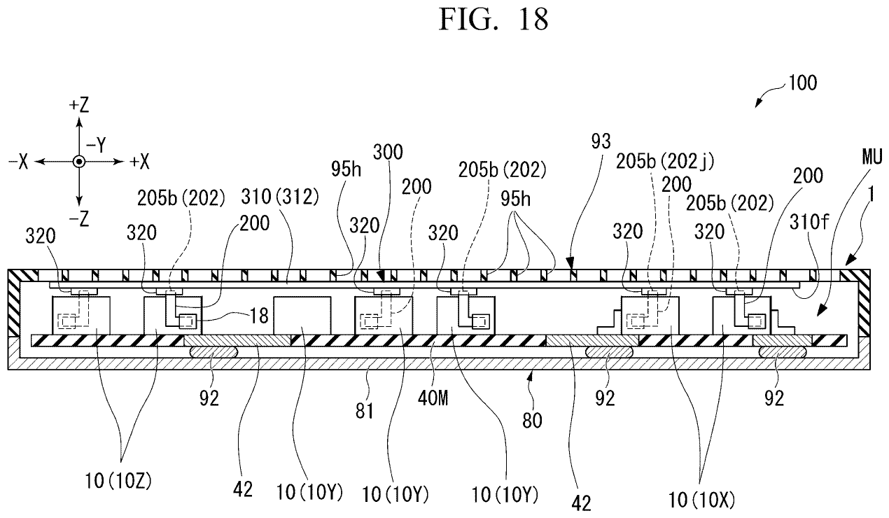

### BRIEF DESCRIPTION OF THE DRAWINGS

[FIG. 1] A cross-sectional view illustrating an electrical connection unit of an embodiment.

[FIG. 2] A perspective view for describing a unit body of the embodiment.

[FIG. 3] A perspective view illustrating a subunit of the embodiment.

[FIG. 4] A partially exploded perspective view of the subunit of the embodiment.

[FIG. 5] A partially exploded perspective view of an electronic component and a connection component of the embodiment.

[FIG. 6] A side view illustrating the electronic component and a connector member of the embodiment.

[FIG. 7] A perspective view illustrating a routing board of the embodiment.

[FIG. 8] A plan view illustrating the routing board of the embodiment.

[FIG. 9] A partially exploded perspective view of the electrical connection unit of the embodiment.

[FIG. 10] A bottom view illustrating the routing board of the embodiment.

[FIG. 11] A plan view illustrating an insulating cover and a routing member of the embodiment.

[FIG. 12] A perspective view illustrating the routing member of the embodiment.

[FIG. 13] A cross-sectional view for describing a method of manufacturing the electrical connection unit of the embodiment.

[FIG. 14] A cross-sectional view for describing the method of manufacturing the electrical connection unit of the embodiment.

[FIG. 15] A cross-sectional view for describing the method of manufacturing the electrical connection unit of the embodiment.

[FIG. 16] A cross-sectional view for describing the method of manufacturing the electrical connection unit of the embodiment.

[FIG. 17] A cross-sectional view for describing the method of manufacturing the electrical connection unit of the embodiment.

[FIG. 18] A cross-sectional view of an electrical connection unit according to a modification example of the embodiment.

### EMBODIMENTS FOR CARRYING OUT THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively. “Sheet-shaped” or “sheet” is not limited to a member having a thickness of 1 mm or more, and a member (so-called a film) having a thickness of less than 1 mm can also be used.

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 9). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 9). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “first direction”. The +Z direction is an example of a “first side in the first direction”. The −Z direction is an example of a “second side in the first direction”. The X direction is an example of a “second direction”. The −X direction is an example of a “first side in the second direction”. The +X direction is an example of a “second side in the second direction”. The Y direction is an example of a “third direction”. The −Y direction is an example of a “first side in the third direction”. The +Y direction is an example of a “second side in the third direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are for convenience of description, and do not limit the gravity direction of the unit body 1 (an installation posture of the unit body 1).

### Embodiment

### <1. Constitution of Assembly>

FIG. 1 is a cross-sectional view illustrating an electrical connection unit 100 of the present embodiment. The electrical connection unit 100 includes a unit body 1, a metal plate (second cover) 80, an insulating cover 93, and a routing member 300. The electrical connection unit 100 is, for example, an in-vehicle device mounted on a vehicle such as an electric vehicle (EV), a hybrid electric vehicle (HEV), or a plug-in hybrid electric vehicle (PHEV). The unit body 1 may be referred to as an “electrical connection box” or a “junction box”, for example. However, the unit body 1 is not limited to a box-shaped device.

### <2. Constitution of Unit Body>

The unit body 1 is electrically connected to an external device via the routing member 300. In the present disclosure, the “external device” is an electric device existing outside unit body 1. Examples of the external device include, but are not limited to, a device including an inverter for driving a motor of a vehicle and the like, a charger for charging a battery pack, and the like.

The unit body 1 includes, for example, a main body MU, an insulating sheet 91 (see FIG. 9), and a plurality of heat transfer members 92.

### <3. Main Body>

First, the main body MU will be described.

FIG. 2 is a perspective view for describing the main body MU. The main body MU is a portion that performs a main function (for example, switching of electrical connection states or overcurrent protection) of the unit body 1. In the present embodiment, the main body MU is divided into a plurality of subunits SU. The main body MU is formed by connecting a plurality of subunits SU. In the present embodiment, the main body MU includes three subunits SU (subunits SUX, SUY, and SUZ). Each subunit SU may be referred to as a “circuit constitution body”.

The subunit SUX has an electrical first function. The subunit SUX includes, for example, a plurality of electronic components 10X and a routing board 40X. The plurality of electronic components 10X are electrically connected to the routing board 40X.

The subunit SUY has an electrical second function. The second function is a function different from the first function. The subunit SUY includes, for example, a plurality of electronic components 10Y and a routing board 40Y. The plurality of electronic components 10Y are electrically connected to the routing board 40Y.

The subunit SUZ has an electrical third function. The third function is a function different from the first function and the second function. The subunit SUZ includes, for example, a plurality of electronic components 10Z and a routing board 40Z. The plurality of electronic components 10Z are electrically connected to the routing board 40Z.

In the present embodiment, the three subunits SUX, SUY, and SUZ are disposed to be arranged in the X direction.

Note that the main body MU need not be divided into a plurality of subunits SU instead of the example described above. That is, the main body MU may be formed by the plurality of electronic components 10 and one routing board 40. In addition, the two or more subunits SU are not limited to the subunits SU having different functions, and may be the subunits SU having the same function.

### <4. Constitution of Subunit>

Next, a constitution of the subunit SU will be described.

As illustrated in FIGS. 3 and 4, the subunit SU includes, for example, a plurality of electronic components 10, a plurality of connection components 20 for component connection, a routing board 40, and a connector member 200. Each connection component 20 is a member forming an energization path in the vertical direction. The connection component 20 may be referred to as a “vertical routing member”.

### <4.1 Electronic Component and Connection Component for Component Connection>

First, the electronic component 10 and the connection component 20 for component connection will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, various sensors (for example, a current sensor or a voltage sensor), or an electronic control unit. The electronic component 10 may be an electronic component unit in which two or more of connectors, fuses, relays, capacitors, branch components, and various sensors are unitized. The electronic component 10 is provided on the +Z direction side of the routing board 40. Note that the type of the electronic component 10 is not limited to the above example. The electronic component 10 is, for example, a heat generating component that generates heat at the time of energization.

The connection component 20 is a component that electrically connects the electronic component 10 to the routing board 40. The connection component 20 forms a part of an energization path in the subunit SU. The connection component 20 is provided on the +Z direction side of the routing board 40. The connection component 20 is made of a metal (for example, copper or a copper alloy). The connection component 20 may be referred to as a “metal component”.

### <4.1.1 Electronic Component>

As illustrated in FIG. 5, the electronic component 10 is an electronic component in which a plurality of terminals 13 are disposed to be arranged at one component end 10e of the electronic component 10. The electronic component 10 includes, for example, a case 11, a component body 12, a plurality of terminals 13, and a plurality of attachment portions 14.

### Case

The case 11 is an outer member that forms most of the outer shape of the electronic component 10. The case 11 is made of, for example, synthetic resin and has an insulating property. The case 11 accommodates the component body 12. The case 11 and the component body 12 may be integrally formed. In the present embodiment, the case 11 is formed in, for example, a rectangular parallelepiped shape.

In the present embodiment, the case 11 has an insulating rib 11a that protrudes in the horizontal direction (for example, the X direction) and extends in the Z direction. The insulating rib 11a has, for example, a plate shape formed in the horizontal direction (for example, the X direction) and the Z direction. The insulating rib 11a extends over the entire length of the case 11 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, a part of the insulating rib 11a is disposed between the first connection portions 21 (described later) of the two connection components 20 connected to the electronic component 10. The insulating rib 11a electrically insulates between the first connection portions 21 of the two connection components 20 connected to the electronic component 10.

As illustrated in FIG. 2, in the present embodiment, at least one of the plurality of electronic components 10 includes a connector connection portion 17. The connector connection portion 17 may be provided in each of the plurality of electronic components 10. In the present embodiment, among the plurality of electronic components 10, for example, the electronic component 10 that is a relay is provided with the connector connection portion 17.

As illustrated in FIG. 6, the connector connection portion 17 is electrically connected to a component body 12 that will be described later provided in the case 11. A connector member 200 that will be described later is detachably connected to the connector connection portion 17. The connector connection portion 17 is one of a so-called female connector and a male connector. In the present embodiment, the connector connection portion 17 is, for example, a male connector. The connector connection portion 17 is made of, for example, a synthetic resin and has an insulating property. The connector connection portion 17 holds a plurality of terminals (not illustrated) electrically connected to an internal circuit of the component body 12.

The connector connection portion 17 is provided on a case side surface (component side surface) 11s directed toward one side in the Y direction in the case 11. The connector connection portion 17 is provided on a case side surface 11s facing the outside in the Y direction of the routing board 40 in the Y direction. As illustrated in FIG. 2, in the electronic component 10A provided on the +Y direction side when the unit body 1 is viewed from the Z direction, the connector connection portion 17 is provided to protrude in the +Y direction from the case side surface 11s directed in the +Y direction. In the electronic component 10B provided on the −Y direction side when the unit body 1 is viewed from the Z direction, the connector connection portion 17 is provided to protrude in the −Y direction from the case side surface 11s directed in the −Y direction. The connector connection portion 17 allows insertion and removal of a first connector 201 of a connector member 200 that will be described later in the X direction. By providing the connector connection portion 17 on the case side surface 11s facing the outside in the Y direction of the routing board 40, the work of attaching and detaching the connector member 200 to and from the connector connection portion 17 can be easily performed from the outside of the routing board 40.

As illustrated in FIGS. 5 and 6, the electronic component 10 includes a connector cover 18 that covers the connector connection portion 17. The connector cover 18 is made of, for example, a synthetic resin and has an insulating property. The connector cover 18 is formed integrally with the case 11. The connector cover 18 has a connector insert hole 18h recessed to one side in the X direction. The connector insert hole 18h is open to the other side in the X direction, and a first portion 205a of the connector member 200 that will be described later can be inserted into the connector insert hole 18h. In the present embodiment, the connector cover 18 is provided at an end of the case side surface 11s on a side away from the connection component 20 in the X direction. In the present embodiment, the connector insert hole 18h is open to the connection component 20 side in the X direction.

### Component Body

The component body 12 is a portion that performs a main function of the electronic component 10. For example, in a case where the electronic component 10 is a relay, the component body 12 includes a switch (for example, a contact) that switches between a conductive state and a non-conductive state. For example, in a case where the electronic component 10 is a fuse, the component body 12 includes a fusion portion that is fused when an overcurrent flows. For example, in a case where the electronic component 10 is a capacitor, the component body 12 includes a portion that stores electric charge.

### Terminal

As illustrated in FIG. 5, the terminal 13 is an electrical connection portion exposed to the outside of the case 11. The terminal 13 is electrically connected to the component body 12 inside the case 11. In the present embodiment, the electronic component 10 includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side.

In the present embodiment, the terminal 13A and the terminal 13B are provided at one component end 10e in the horizontal direction (for example, the X direction) of the electronic component 10. The terminal 13A and the terminal 13B are disposed to be arranged in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the X direction). An inner circumferential surface of the attachment hole 13h of the electronic component 10 has a screw groove.

### Attachment Portion

The attachment portion 14 is a portion for fixing the electronic component 10. The attachment portion 14 has an attachment hole 14h to which a fastening member 112 (for example, a screw or a bolt; and see FIG. 9) that will be described later is attached. The attachment hole 14h is open in the Z direction. The attachment hole 14h is an insertion hole through which the fastening member 112 passes. A fixing destination of the attachment portion 14 will be described later.

### <4.1.2 Connection Component>

The connection component 20 is a component that electrically connects the electronic component 10 to the routing board 40. In the present embodiment, the connection component 20 electrically connects the electronic component 10 to the bus bar 42 (see FIG. 4) included in the routing board 40. The connection component 20 includes, for example, a first connection portion 21 and a second connection portion 22.

### First Connection Portion

The first connection portion 21 of the connection component 20 is a portion connected to the terminal 13 of the electronic component 10. The first connection portion 21 is a plate-shaped or prismatic portion extending in the Z direction. The first connection portion 21 extends in the Z direction along a component end 10e (for example, a flat surface of the component end 10e in the X direction) which is one end portion of the electronic component 10. The first connection portion 21 is a standing portion that stands in the Z direction with respect to the routing board 40 (for example, with respect to a bus bar 42 that will be described later). The first connection portion 21 is adjacent to the electronic component 10 in the horizontal direction (for example, the X direction). For example, the first connection portion 21 is adjacent to the terminal 13 of the electronic component 10 in the horizontal direction (for example, the X direction), and is connected to the terminal 13 of the electronic component 10 from the horizontal direction (for example, the X direction).

The first connection portion 21 of the connection component 20 has a first attachment hole 21h through which the fastening member 71 (for example, a screw or a bolt) passes. The first attachment hole 21h is open in the horizontal direction (for example, the X direction). The fastening member 71 that has passed through the first attachment hole 21h is engaged with the attachment hole 13h of the terminal 13 of the electronic component 10, and thus the first connection portion 21 is physically and electrically connected to the terminal 13 of the electronic component 10.

### Second Connection Portion

The second connection portion 22 of the connection component 20 is a portion connected to the bus bar 42 (see FIG. 9). The second connection portion 22 protrudes in the horizontal direction (for example, the X direction) from an end 10f of the first connection portion 21 on the −Z direction side. The second connection portion 22 is a plate portion provided in the horizontal direction and along the routing board 40. The second connection portion 22 is adjacent to the bus bar 42 in the Z direction and is connected to the bus bar 42 from the +Z direction. The second connection portion 22 of the connection component 20 is physically and electrically connected to the bus bar 42 by being attached from the +Z direction to the fastening member 43 (for example, a screw or a bolt; and see FIG. 3) protruding from the bus bar 42 in the +Z direction. In the present embodiment, the second connection portion 22 of the connection component 20 has a second attachment hole 22h through which the fastening member 43 passes. The second attachment hole 22h is open in the Z direction. In the second connection portion 22, the fastening member 43 passes through the second attachment hole 22h. The engagement member 44 (for example, a nut; and see FIG. 3) is engaged with the tip of the fastening member 43 that has passed through the second attachment hole 22h, and thus the second connection portion 22 is fixed to the bus bar 42. In the present embodiment, the first connection portion 21 and the second connection portion 22 form a single connection component 20 having an L shape in a side view viewed from the Y direction.

The connection component 20 is a heat storage member (heat absorbing member) that increases the heat capacity of the energization path of the unit body 1. The connection component 20 stores (absorbs) at least a part of heat generated by the electronic component 10, for example. Alternatively/additionally, the connection component 20 may store (absorb) at least a part of heat generated by the bus bar 42 due to energization. The connection component 20 may be referred to as a “heat storage component” or a “heat absorbing component”.

### 4.2 Routing Board

Next, the routing board 40 will be described.

FIG. 7 is a perspective view illustrating the routing board 40. The routing board 40 is a member that forms at least a part of an energization path between the plurality of electronic components 10 and/or at least a part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the “plate shape” is not limited to a completely flat shape, and may include a case where a fixing structure, a rib, or the like protruding in the Z direction is partially present. In the present embodiment, the routing board 40 has a plate shape formed in the X direction and the Y direction.

The routing board 40 includes, for example, a base plate 41, one or more (for example, a plurality of) bus bars 42, and a plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board 40 may be formed by another structure instead of the insert molding.

### Base Plate

The base plate 41 is a holding member that integrally holds the plurality of bus bars 42 arranged in the horizontal direction at intervals. The base plate 41 is made of, for example, synthetic resin and has an insulating property. The base plate 41 electrically insulates the plurality of bus bars 42 from each other. The base plate 41 is an example of a “base member”. The base plate 41 may be referred to as an “insulating substrate”. The base plate 41 includes, for example, a flat surface portion 51 and a plurality of fixing portions 52.

The flat surface portion 51 is a portion formed in a plate shape in the base plate 41. The flat surface portion 51 has a plate shape formed in the horizontal direction. The flat surface portion 51 forms a main portion of the base plate 41. The flat surface portion 51 forms a base portion (insulating base portion) of the base plate 41. In the present embodiment, the flat surface portion 51 extends over the entire width in the X direction of the base plate 41 and over the entire width in the Y direction of the base plate 41 except for four corner portions of the base plate 41.

The flat surface portion 51 has a first surface 51a and a second surface 51b. The first surface 51a is a surface directed in the +Z direction. The first surface 51a is a flat surface provided in the horizontal direction. The first surface 51a faces the plurality of electronic components 10 and faces the insulating cover 93 (see FIG. 1) of the unit body 1. The second surface 51b is located on the side opposite to the first surface 51a. The second surface 51b is a surface directed in the −Z direction. The second surface 51b is a flat surface provided in the horizontal direction. The second surface 51b faces the metal plate 80 (see FIG. 1). A thickness direction (plate thickness direction) of the flat surface portion 51 is the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole.

Each accommodation portion 55 has an outer shape corresponding to the shape of the bus bar 42 to be accommodated when viewed from the Z direction.

### Bus Bar

The bus bar 42 is a routing member (electrical connection member) included in the routing board 40. The bus bar 42 is, for example, a routing member for electrically connecting the plurality of electronic components 10. Alternatively, the bus bar 42 may be a routing member for connecting the electronic component 10 to an external device. The bus bar 42 is made of a metal (for example, copper or a copper alloy) and has conductivity.

At least a part of each bus bar 42 has a plate shape formed in the horizontal direction. At least a part of each bus bar 42 is accommodated in the accommodation portion 55 and extends along the flat surface portion 51. That is, at least a part of each bus bar 42 extends along the first surface 51a of the flat surface portion 51. At least a part of each bus bar 42 extends in the horizontal direction in the accommodation portion 55. In the present embodiment, each bus bar 42 has a plate shape formed in the horizontal direction over the entire bus bar 42. Each of the bus bars 42 is accommodated in the accommodation portion 55 over the entire length of the bus bar 42 and extends along the flat surface portion 51. Hereinafter, a portion of each bus bar 42 that is accommodated in the accommodation portion 55 and extends along the flat surface portion 51 may be referred to as a “plate portion 42p”. The bus bar 42 is a member that forms a horizontal energization path. The bus bar 42 may be referred to as a “horizontal routing member”. Among the plurality of bus bars 42, some bus bars 42 may be, for example, bus bars included in a positive electrode line of the unit body 1. Among the plurality of bus bars 42, some bus bars 42 other than the bus bars included in the positive electrode line may be, for example, bus bars included in a negative electrode line of the unit body 1.

FIG. 8 is a plan view illustrating the routing board 40. The plate portion 42p of each bus bar 42 has, for example, a connection portion 61 and an extending portion 63.

The connection portion 61 is a portion in contact with one connection component 20. The connection component 20 is a connection component that connects one electronic component 10 to the bus bar 42. The connection portion 61 is a portion of the bus bar 42 overlapping the connection component 20 when viewed from the Z direction. The connection portion 61 is adjacent to the connection component 20 in the Z direction and is connected to the connection component 20 from the Z direction. For example, each connection portion 61 is located on the +X direction side or the −X direction side with respect to the electronic component 10 when viewed from the Z direction. Each connection portion 61 is electrically connected to the terminal 13A or the terminal 13B of the electronic component 10 via the connection component 20.

The extending portion 63 extends from the connection portion 61 in the X direction or the Y direction. The extending portion 63 is continuously connected to the connection portion 61.

In the present embodiment, the connection portion 61 and the extending portion 63 have a plate shape formed in the horizontal direction. In the present embodiment, each bus bar 42 is accommodated in the accommodation portion 55 at least over the connection portion 61 and the extending portion 63 and extends along the flat surface portion 51. For example, the connection portion 61 and the extending portion 63 are accommodated in the accommodation portion 55 and extend along the flat surface portion 51.

### Fastening Member

The fastening member 43 is a component for fixing the bus bar 42 and the connection component 20. The fastening member 43 is, for example, a caulking bolt fixed to the bus bar 42.

In the present embodiment, the connection portion 61 of the bus bar 42 has a through-hole 42h. The through-hole 42h penetrates the bus bar 42 in the Z direction. The fastening member 43 is, for example, a bolt having a shaft 43a and a head 43b (see FIG. 14). A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 42h of the bus bar 42. With this fixation, the fastening member 43 is electrically and physically connected to the bus bar 42 in a state in which the shaft 43a protrudes in the +Z direction from the through-hole 42h of the bus bar 42. The fastening member 43 is not limited to caulking fixation, and may be fixed to the bus bar 42 through welding or other methods.

### <5. Connector Member>

Next, the connector member 200 will be described.

As illustrated in FIGS. 5 and 6, the connector member 200 connects the connector connection portion 17 provided in the electronic component 10 to a relay connector 320 of a routing member 300 that will be described later. The connector member 200 is interposed between the connector connection portion 17 and the relay connector 320. As illustrated in FIG. 6, the connector member 200 includes a first connector 201, a second connector 202, a connection harness 203, and a connector holding portion 205.

The first connector 201 is detachably connected to the connector connection portion 17 of the electronic component 10. The first connector 201 is one of a so-called male connector and a so-called female connector. In the present embodiment, the first connector 201 is, for example, a female connector. The first connector 201 has a first end 201j to which the connector connection portion 17 is detachably connected. The first end 201j is made of, for example, a synthetic resin and has an insulating property. The first end 201j holds a plurality of terminals (not illustrated) electrically connected to one end of a wiring (not illustrated) of the connection harness 203. The first end 201j is formed in a shape that can be inserted into and removed from the connector connection portion 17. The first end 201j and the connector connection portion 17 include engagement claws (not illustrated) and the like that can be engaged with each other in a state in which the first end 201j and the connector connection portion 17 are connected, and each terminal of the first end portion 201j and a corresponding terminal of the connector connection portion 17 are electrically connected. The first end 201j is an example of an “end”.

The second connector 202 is disposed in the +Z direction. The second connector 202 is detachably connected to the relay connector 320. The second connector 202 is one of a so-called female connector and a male connector. In the present embodiment, the second connector 202 is, for example, a male connector. The second connector 202 has a second end 202j to which the relay connector 320 is detachably connected. The second end 202j is made of, for example, a synthetic resin and has an insulating property. The second end 202j holds a plurality of terminals (not illustrated) electrically connected to the other end of a routing (not illustrated) of the connection harness 203. The second end 202j is formed in a shape that can be inserted into and removed from the relay connector 320.

The connection harness 203 electrically connects a plurality of terminals (not illustrated) of the first connector 201 to a plurality of terminals (not illustrated) of the second connector 202. The plurality of connection harnesses 203 include a plurality of routings 203w that electrically connect the plurality of terminals of the first connector 201 to the plurality of terminals of the second connector 202, respectively.

The connector holding portion 205 holds the first connector 201 and the second connector 202. The connector holding portion 205 has a hollow cylindrical shape, and accommodates the first connector 201, the second connector 202, and the connection harness 203 therein. The connector holding portion 205 is made of, for example, a synthetic resin and has an insulating property. The connector holding portion 205 is formed in an L shape in a side view viewed from the Y direction. The connector holding portion 205 integrally includes a first portion 205a and a second portion 205b.

The first portion 205a holds the first connector 201. The first portion 205a extends in the X direction in a state in which the first connector 201 is connected to the connector connection portion 17. The first connector 201 is held at an end on one side in the X direction of the first portion 205a. The first end 201j of the first connector 201 is provided toward one side in the X direction. The end on one side in the X direction of the first portion 205a of the connector holding portion 205 is inserted into the connector insert hole 18h of the connector cover 18 provided in the electronic component 10. The first connector 201 is connected to the connector connection portion 17 in the connector insert hole 18h.

The second portion 205b is connected to the end on the other side in the X direction of the first portion 205a. The second portion 205b extends in the +Z direction from a portion connected to the first portion 205a. The second portion 205b holds the second connector 202. The second connector 202 is held at an end of the second portion 205b in the +Z direction. The second connector 202 is provided with the second end 202j directed in the +Z direction.

### <6. Insulating Sheet and Heat Transfer Member>

Next, the insulating sheet 91 and the heat transfer member 92 will be described.

### <6.1 Insulating Sheet>

FIG. 9 is a partially exploded perspective view of the unit body 1. The insulating sheet 91 is an insulating member for electrically insulating the metal plate 80 and the bus bar 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 has a sheet shape formed in the horizontal direction. The insulating sheet 91 is disposed between a flat surface portion 81 that will be described later of the metal plate 80 and the routing board 40 of each subunit SU. For example, the insulating sheet 91 is disposed between the flat surface portion 81 of the metal plate 80 and the plurality of heat transfer members 92.

In the present embodiment, the insulating sheet 91 is attached to the flat surface portion 81 of the metal plate 80. The insulating sheet 91 has a notch or an opening for avoiding a fixing portion 82 and a fixing portion 83, which will be described later, of the metal plate 80. Note that, instead of the above example, the insulating sheet 91 may be provided between the routing board 40 of each subunit SU and the plurality of heat transfer members 92.

### <6.2 Heat Transfer Member>

The heat transfer member 92 is a member for transferring heat generated by the electronic component 10 at the time of energization and/or heat generated by the bus bar 42 itself at the time of energization to the metal plate 80. The heat transfer member 92 is, for example, a heat transfer sheet (for example, a thermally conductive silicone sheet) having elasticity. However, the heat transfer member 92 is not limited to the above example, and may be a heat transfer member made of a thermally conductive gel or another material.

FIG. 10 is a bottom view illustrating the routing board 40. In the present embodiment, the plurality of heat transfer members 92 are partially provided in the routing board 40. For example, the plurality of heat transfer members 92 are disposed at positions overlapping a part of the bus bar 42 when viewed from the Z direction. More specifically, the plurality of heat transfer members 92 are disposed at positions overlapping a part of the bus bar 42 in the vicinity of the electronic component 10 when viewed from the Z direction. In the present embodiment, the plurality of heat transfer members 92 are disposed at positions overlapping the connection component 20 when viewed from the Z direction.

The heat transfer member 92 is disposed between the metal plate 80 and the bus bar 42. The heat transfer member 92 transfers heat transferred from the electronic component 10 to the bus bar 42 and/or heat generated by the bus bar 42 from the bus bar 42 to the metal plate 80.

### <7. Metal Plate and Insulating Cover>

Next, the metal plate 80 and the insulating cover 93 will be described.

### <7.1 Metal Plate>

As illustrated in FIG. 9, the metal plate 80 covers the unit body 1 from the −Z direction. The metal plate 80 is a member for securing rigidity of the unit body 1 and enhancing the heat dissipation property of the unit body 1. The metal plate 80 is made of a metal (for example, aluminum or an aluminum alloy). The metal plate 80 has, for example, a higher rigidity than the insulating sheet 91. The metal plate 80 is an example of a “second cover”. The metal plate 80 may be referred to as a “rigid member”. The insulating cover 93 that will be described later is attached to the metal plate 80.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of end portions of the metal plate 80 in the longitudinal direction and are separated in the X direction. The third end 80e3 and the fourth end 80e4 are a pair of end portions of the metal plate 80 in the lateral direction and are separated in the Y direction. The metal plate 80 includes, for example, a flat surface portion 81, a plurality of fixing portions 82, and a plurality of fixing portions 83.

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the three subunits SU from below. The flat surface portion 81 faces the routing boards 40 of the three subunits SU.

The metal plate 80 has an outer peripheral projection portion 89 that further projects in the X direction and the Y direction than the main body MU when viewed from the Z direction. The outer peripheral projection portion 89 is a portion to which the insulating cover 93 that will be described later is attached. In the present embodiment, the outer peripheral projection portion 89 is formed to rise in the +Z direction from the outer peripheral portion of the flat surface portion 81.

The fixing portion 82 is a fixing portion for fixing the base plate 41 of each subunit SU to the metal plate 80. The fixing portion 82 is provided at a position corresponding to the fixing portion 52 of the base plate 41 of each subunit SU when viewed from the Z direction. The fixing portion 82 is a cylindrical or prismatic boss protruding in the +Z direction from the flat surface portion 81 of the metal plate 80.

The fixing portion 83 is a fixing portion for directly fixing the electronic component 10 of each subunit SU to the metal plate 80 without interposing the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81.

### <7.2 Insulating Cover>

Referring to FIG. 1 again, the insulating cover 93 will be described. The insulating cover 93 is a member for securing safety of the main body MU with respect to the energization path. The insulating cover 93 is an example of a “first cover”. The insulating cover 93 is made of, for example, a synthetic resin and has an insulating property. The insulating cover 93 covers the unit body 1 from the +Z direction. In the present embodiment, the insulating cover 93 covers the entire plurality of subunits SU provided on the metal plate 80 from the +Z direction.

The insulating cover 93 has, for example, a box shape that is open on the −Z direction side. That is, as illustrated in FIGS. 1 and 12, the insulating cover 93 integrally includes a plate-shaped portion 95 and a peripheral wall portion 96. The plate-shaped portion 95 is provided at an interval in the +Z direction with respect to the metal plate 80. The plate-shaped portion 95 has a rectangular plate shape formed in the X direction when viewed from the Z direction. The plate-shaped portion 95 has a holding surface 95f that holds the routing member 300 that will be described later on the +Z direction side.

The peripheral wall portion 96 rises in the −Z direction from the outer peripheral portion of the plate-shaped portion 95. The peripheral wall portion 96 includes a first wall portion 96a, a second wall portion 96b, a third wall portion 96c, and a fourth wall portion 96d. The first wall portion 96a and the second wall portion 96b are separated in the X direction. Each of the first wall portion 96a and the second wall portion 96b extends in the Y direction when viewed from the Z direction. The third wall portion 96c and the fourth wall portion 96d are separated in the Y direction. Each of the third wall portion 96c and the fourth wall portion 96d extends in the X direction when viewed from the Z direction. The first wall 96a, the second wall 96b, the third wall 96c, and the fourth wall 96d constituting the peripheral wall portion 96 surround the unit body 1 in the horizontal direction (the X direction and the Y direction).

The tip of the peripheral wall portion 96 is connected to the outer peripheral projection portion 89 of the metal plate 80 via appropriate connecting means such as fitting, screwing, adhesion, or welding. As a result, the unit body 1 is covered with the insulating cover 93 and the metal plate 80.

As illustrated in FIG. 11, the insulating cover 93 has a plurality of vent holes 95h at least in the plate-shaped portion 95. The plurality of vent holes 95h penetrate the plate-shaped portion 95 in the Z direction. The plurality of vent holes 95h may be formed to penetrate the peripheral wall portion 96 in addition to the plate-shaped portion 95. Each vent hole 95h releases heat generated by the electronic component 10 of the unit body 1 to the outside of the insulating cover 93.

As illustrated in FIGS. 1 and 11, the plate-shaped portion 95 has a plurality of connector accommodation holes 95z. The plurality of connector accommodation holes 95z penetrate the plate-shaped portion 95 in the Z direction. A plurality of relay connectors 320 that will be described later are accommodated in the plurality of connector accommodation holes 95z.

### <8. Routing Member>

As illustrated in FIGS. 1, 11, and 12, the routing member 300 includes a support 310 and a plurality of relay connectors 320. As illustrated in FIG. 1, in the present embodiment, the routing member 300 is disposed on the +Z side with respect to the insulating cover 93. That is, the routing member 300 is provided outside the unit body 1. The routing member 300 is connected to an external device connected to the unit body 1, such as a device including an inverter for driving a motor of a vehicle and the like, or a charger for charging a battery pack.

The support 310 integrally supports the plurality of relay connectors 320. The support 310 has, for example, a flat plate shape and is formed of a flexible board or a solid board. The support 310 is provided along the holding surface 95f of the plate-shaped portion 95. As illustrated in FIG. 12, the support 310 has a predetermined wiring pattern 312.

The plurality of relay connectors 320 are fixed to a surface 310f of the support 310 directed in the −Z direction. The plurality of relay connectors 320 are respectively accommodated in the plurality of connector accommodation holes 95z when viewed from the Z direction. As illustrated in FIG. 1, the plurality of relay connectors 320 are provided at positions corresponding to the second connectors 202 of the connector member 200. Specifically, the plurality of relay connectors 320 are disposed at positions facing the second connectors 202 of the connector members 200 provided in the plurality of electronic components 10 in the Z direction. Each of the plurality of relay connectors 320 is connected to a second end 202j of the second connector 202.

The plurality of relay connectors 320 can be inserted into and removed from the second connectors 202 of the plurality of connector members 200 in the +Z direction. That is, each relay connector 320 is detachably connected to the corresponding second connector 202. Each relay connector 320 is one of a so-called male connector and female connector. In the present embodiment, the relay connector 320 is, for example, a female connector. Each relay connector 320 is made of, for example, a synthetic resin and has an insulating property. Each relay connector 320 holds a plurality of terminals (not illustrated) electrically connected to the wiring pattern 312 of the support 310.

Each relay connector 320 is formed in a shape that can be inserted into and removed from the second end 202j of the second connector 202. The plurality of relay connectors 320 are respectively provided to be insertable into and removable from the second ends 202j of the plurality of connector members 200 in the Z direction. The second end 202j and the relay connector 320 include engagement claws (not illustrated) and the like that can be engaged with each other in a state in which the second end 202j and the relay connector 320 are connected, and each terminal of the second connector 202 and a corresponding terminal of the relay connector 320 are electrically connected.

As illustrated in FIGS. 11 and 12, in the present embodiment, the support 310 of the routing member 300 is provided along at least a part of the plate-shaped portion 95. In the present embodiment, the support 310 is provided not to cover the entire plate-shaped portion 95 but to cover only a part of the plate-shaped portion 95. In the present embodiment, for example, the support 310 extends along the outer peripheral portion of the plate-shaped portion 95 to overlap the plurality of relay connectors 320 when viewed from the Z direction. In the present embodiment, the support 310 is formed in, for example, a U shape when viewed from the Z direction, and includes a pair of extending portions 310a and 310b and a connection portion 310c. The pair of extending portions 310a and 310b are provided at both ends of the plate-shaped portion 95 in the Y direction. Each of the pair of extending portions 310a and 310b extends in a belt shape in the X direction. The connection portion 310c extends in a belt shape in the Y direction on one side in the X direction (for example, the −X direction side) and connects the ends of the pair of extending portions 310a and 310b to each other. The shape of the support 310 when viewed from the Z direction is not limited to a U shape and may be any shape. By providing the support 310 to cover only a part of the plate-shaped portion 95, as illustrated in FIG. 11, a plurality of vent holes 95h are open in a portion where the plate-shaped portion 95 is not covered with the support 310. The plurality of vent holes 95h are not formed at positions overlapping the support 310 of the routing member 300, and are formed at positions shifted from the routing member 300 when viewed from the Z direction. The support 310 may be provided to cover the entire plate-shaped portion 95.

The support 310 is provided at a position shifted from the electronic component 10H having a heat generation property such as a relay among the plurality of electronic components 10 of the unit body 1 when viewed from the Z direction. With this constitution, the support 310 is provided to avoid the upper side of the electronic component 10H having the heat generation property. The routing member 300 may have a heat dissipation opening 311 penetrating the support 310 in the Z direction. In this case, the heat dissipation opening 311 may be formed to be connected to another opening that the plate-shaped portion 95 has and that penetrates in the Z direction. The heat dissipation opening 311 is preferably formed in the vicinity of the electronic component 10H.

### <9. Method of Manufacturing Unit Body>

Next, a method of manufacturing the unit body 1 will be described.

FIGS. 13 to 17 are cross-sectional views for describing the method of manufacturing the unit body 1. In the routing board 40 of each subunit SU, the base plate 41 and the plurality of bus bars 42 are integrated through insert molding or another method in a state in which the fastening member 43 is fixed to the bus bar 42. This integration allows the routing board 40 of each subunit SU to be prepared in advance.

### First Step

FIG. 13 illustrates a first step. In the first step, the connection component 20 is fixed to the terminal 13 of the electronic component 10 by using the fastening member 71. This fixation forms an assembly component SA in which the electronic component 10 and the connection component 20 are integrated.

The first step is performed, for example, as follows. First, the electronic component 10 is placed on a placement table MP in a posture in which the attachment hole 13h of the terminal 13 of the electronic component 10 is directed in the vertical direction. Next, the connection component 20 is placed on the electronic component 10 in a posture in which the first attachment hole 21h of the connection component 20 is directed in the vertical direction. The first attachment hole 21h of the connection component 20 and the attachment hole 13h of the terminal 13 of the electronic component 10 are aligned. The first step is performed in a state in which the electronic component 10 and the connection component 20 are in a first posture. The first posture is a posture in which the attachment hole 13h and the first attachment hole 21h are directed in the vertical direction.

Next, the fastening member 71 is inserted into the first attachment hole 21h of the connection component 20 from the vertical direction. The fastening member 71 that has passed through the first attachment hole 21h of connection component 20 is engaged with the attachment hole 13h of the terminal 13 of the electronic component 10. This engagement forms the assembly component SA in which the electronic component 10 and the connection component 20 are integrated.

### Second Step

FIG. 14 illustrates a second step. In the second step, the assembly component SA is fixed to the routing board 40 of each subunit SU. For example, the connection component 20 included in the assembly component SA is fixed to the bus bar 42 included in the routing board 40. This fixation electrically connects electronic component 10 to bus bar 42.

The second step is performed, for example, as follows. As described above, in the routing board 40, the fastening member 43 is fixed to the bus bar 42. The fastening member 43 protrudes in the vertical direction from the bus bar 42. The fastening member 43 is inserted into the second attachment hole 22h of the second connection portion 22 of the connection component 20 in the vertical direction, and the assembly component SA is placed on the routing board 40. Next, the engagement member 44 (for example, a nut) is engaged with the upper end of the fastening member 43 from the vertical direction. This engagement fixes the second connection portion 22 of the connection component 20 included in the assembly component SA to the bus bar 42. This fixation completes each subunit SU.

### Third Step

FIG. 15 illustrates a third step. In the third step, each subunit SU is attached to the metal plate 80. The third step is performed, for example, as follows. First, the insulating sheet 91 is attached to the surface of the flat surface portion 81 of the metal plate 80. Next, the heat transfer member 92 is fixed to the lower surface of each subunit SU with an adhesive or the like. Next, each subunit SU is placed on the metal plate 80 with the insulating sheet 91 and the heat transfer member 92 interposed therebetween. The fixing portion 52 of each subunit SU is fixed to the fixing portion 82 of the metal plate 80 via the fastening member 111.

### Fourth Step

FIG. 16 illustrates a fourth step. In the fourth step, the attachment portion 14 of the electronic component 10 of each subunit SU is fixed to the fixing portion 83 of the metal plate 80 via the fastening member 112. In the fourth step, the connector member 200 is connected to the connector connection portion 17 of the electronic component 10. The fourth step may be performed together with the third step.

### Fifth Step

FIG. 17 illustrates a fifth step. Before the fifth step is executed, the routing member 300 and the insulating cover 93 are integrated. In the fifth step, the insulating cover 93 to which the routing member 300 is attached is attached to the metal plate 80 in the vertical direction. In this case, the plurality of relay connectors 320 of the routing member 300 are connected to the second portion 205b of each connector member 200. In this state, the assembly of the electrical connection unit 100 is completed.

### <10. Advantages>

In the present embodiment, the electrical connection unit 100 includes the insulating cover 93 that covers the unit body 1 from the +Z direction, and the metal plate 80 that covers the unit body 1 from the −Z direction and to which the insulating cover 93 is attached. The routing member 300 having the relay connector 320 connected to the electronic component 10 via the connector member 200 is provided integrally with the insulating cover 93. According to such a constitution, since the routing member 300 and the insulating cover 93 are integrated, the attachment of the insulating cover 93 to the metal plate 80 and the plurality of relay connectors 320 to the connector member 200 can be performed simultaneously. As a result, the assemblability of the electrical connection unit 100 can be improved.

In the present embodiment, the metal plate 80 has a plate shape having a higher rigidity than the base plate 41. The insulating cover 93 includes the plate-shaped portion 95 having the holding surface 95f that holds the routing member 300, and the peripheral wall portion 96 rising in the −Z direction from the outer peripheral portion of the plate-shaped portion 95 and connected to the metal plate 80. According to such a constitution, a strong casing that accommodates the unit body 1 can be constituted by the insulating cover 93 and the metal plate 80.

In the present embodiment, the insulating cover 93 has the plurality of vent holes 95h at least in the plate-shaped portion 95. According to such a constitution, heat from the electronic component 10 can be released to the outside of the insulating cover 93 through the vent hole 95h. As a result, the operation stability of the unit body 1 can be enhanced.

In the present embodiment, the plurality of vent holes 95h are formed at positions shifted from the routing member 300 when viewed from the Z direction. According to such a constitution, the influence of the heat released from the vent hole 95h is suppressed from reaching the routing member 300.

In the present embodiment, the plate-shaped portion 95 has the plurality of connector accommodation holes 95z into which the plurality of relay connectors 320 are respectively inserted. According to such a constitution, the plurality of relay connectors 320 can be positioned with respect to the plate-shaped portion 95 of the insulating cover 93. As a result, when the insulating cover 93 is attached to the metal plate 80, the plurality of relay connectors 320 can be easily connected to the second ends 202j of the plurality of connector members 200, and the assemblability is improved.

In the present embodiment, the routing member 300 has the heat dissipation opening 311 penetrating the support 310 in the Z direction. According to such a constitution, heat from the electronic component 10 can be released through the heat dissipation opening 311 of the routing member 300. As a result, the operation stability of the unit body 1 can be further enhanced.

In the present embodiment, the routing member 300 is provided at a position shifted from the electronic component 10H having the heat generation property when viewed from the Z direction. According to such a constitution, the influence of heat from the electronic component 10H having the heat generation property is less likely to reach the routing member 300. As a result, the operation stability of the unit body 1 can be further enhanced.

### <10. Modification Examples>

Next, several modification examples will be described. Note that constitutions other than those described below in each modification example are the same as the constitutions of the above-described embodiment.

In the above-described embodiment, the routing member 300 is provided on the +Z direction side with respect to the insulating cover 93, but the present invention is not limited thereto.

For example, as illustrated in FIG. 18, the routing member 300 may be provided on the −Z direction side of the insulating cover 93. That is, the routing member 300 may be accommodated in the unit body 1.

Several embodiments and modification examples have been described above. However, the embodiment and the modification examples are not limited to the examples described above. For example, a plurality of embodiments may be implemented in combination with each other.

### DESCRIPTION OF REFERENCE SYMBOLS

1 Unit body
10 Electronic component
10A Electronic component
10B Electronic component
10H Electronic component
10X Electronic component
10Y Electronic component
10Z Electronic component
13 Terminal
17 Connector connection portion
41 Base plate (base member)
42 Bus bar
51 Flat surface portion
80 Metal plate (second cover)
81 Flat surface portion
93 Insulating cover (first cover)
95 Plate-shaped portion
95f Holding surface
95h Vent hole
95z Connector accommodation hole
96 Peripheral wall portion
100 Electrical connection unit
200 Connector member
201 First connector
202 Second connector
300 Routing member
310 Support
311 Heat dissipation opening
320 Relay connector

1. An electrical connection unit comprising:
a unit body;
a first cover that covers the unit body from a first side in a first direction;
a second cover that covers the unit body from a second side in the first direction, and to which the first cover is attached; and
a routing member that is provided integrally with the first cover and detachably connected to the unit body,
wherein
the unit body includes
an insulating base member including a flat surface portion having a plate shape or a sheet shape,
a conductive bus bar held by the flat surface portion,
a plurality of electronic components provided on the first side in the first direction with respect to the base member and each having a terminal electrically connected to the bus bar and a connector connection portion, and
a plurality of connector members each including a first connector detachably connected to the connector connection portion and a second connector disposed in the first direction, and
the routing member includes
a plurality of relay connectors that are provided at positions corresponding to the second connectors of the plurality of connector members when viewed from the first direction, and are insertable into and removable from the second connectors of the plurality of connector members in the first direction, and
a support that integrally supports the plurality of relay connectors.

2. The electrical connection unit according to claim 1, wherein
the second cover has a plate shape having a higher rigidity than the base member, and
the first cover includes
a plate-shaped portion provided at an interval from the second cover in the first direction and having a holding surface that holds the routing member, and
a peripheral wall portion rising from an outer peripheral portion of the plate-shaped portion to the second side in the first direction and connected to the second cover.

3. The electrical connection unit according to claim 2, wherein
the first cover has a plurality of vent holes at least in the plate-shaped portion.

4. The electrical connection unit according to claim 3, wherein
the plurality of vent holes are formed at positions shifted from the routing member when viewed from the first direction.

5. The electrical connection unit according to claim 2, wherein
the plate-shaped portion includes a plurality of connector accommodation holes that penetrate the plate-shaped portion in the first direction and into which the plurality of relay connectors are respectively inserted.

6. The electrical connection unit according to claim 1, wherein
the routing member includes a heat dissipation opening penetrating the support in the first direction.

7. The electrical connection unit according to claim 1, wherein
the routing member is provided at a position shifted from an electronic component having a heat generation property among the electronic components when viewed in the first direction.
